(19) United States
(12) Patent Application Publication
(10) Pub. No.: US 2024/0230797 A9
(43) Pub. Date: Jul. 11, 2024

(54) SPIN VALVE DEVICE AND METHOD FOR FORMING A SPIN VALVE DEVICE

(71) Applicant: Infineon Technologies AG, Neubiberg (DE)

(72) Inventors: Dieter SUESS, Wien (AT); Armin SATZ, Villach (AT); Wolfgang RABERG, Sauerlach (DE); Klemens PRÜGL, Regensburg (DE); Mathias KLAEUI, Mainz (DE)

(21) Appl. No.: 18/487,593

(22) Filed: Oct. 16, 2023

(30) Foreign Application Priority Data
Oct. 25, 2022 (DE) 102022128167.1

(51) Int. Cl. G01R 33/09; H01F 10/32; H10N 50/01; H10N 50/10

(52) U.S. Cl. CPC G01R 33/093; G01R 33/098; H01F 10/3268; H10N 50/01; H10N 50/10

(57) ABSTRACT

The present disclosure proposes a spin valve device comprising a layer stack. The layer stack comprises one or more layers forming a unidirectionally magnetized reference system, a vortex-magnetized free layer, a non-magnetic layer separating the reference system from the free layer, and one or more layers forming a bias structure being exchange-coupled to the free layer, the bias structure having a vortex-magnetization with closed flux of a predetermined rotation direction.

### CROSS REFERENCE TO RELATED APPLICATION

This application claims priority to German Patent Application No. 102022128167.1 filed on Oct. 25, 2022, the content of which is incorporated by reference herein in its entirety.

### TECHNICAL FIELD

The present disclosure relates to generally relates to magneto-resistive structures, and, more particularly to spin valve devices exploiting the TMR (TMR: tunnel magnetoresistance) or GMR effects (GMR: giant magnetoresistance).

### BACKGROUND

A spin valve is a device, comprising two or more conducting magnetic materials, whose electrical resistance can change depending on a relative alignment of magnetization in different layers. The electrical resistance change may be a result of the GMR effect or the TMR effect, for example. In a simple case, a spin valve comprises a non-magnetic material sandwiched between two ferromagnets, one of which is fixed (pinned) by an antiferromagnet which acts to raise its magnetic coercivity and behaves as a “hard” layer, while the other is free (unpinned) and behaves as a “soft” layer.

Spin valves may be used in the form of Wheatstone bridge configurations to sense magnetic fields. In an ideal case, the spin valves used in the bridge configuration are matched in terms of electrical resistance and magnetic sensitivity over different operating conditions (e.g., temperature, supply voltage).

A spin valve may be deposited on a substrate, such as a semiconductor die, and comprises a magnetic free layer and one or more layers forming a ferromagnetic reference system. The magnetic free layer and the reference system are separated by a thin non-magnetic layer which is also referred to as tunnel barrier or junction. The free layer and the reference system may employ ferromagnets or ferrimagnets with different coercivities (by using different materials or different film thicknesses), or a ferromagnetic or ferrimagnetic layer of the reference system may be coupled with an antiferromagnet (exchange bias). The free layer may be configured in such a way that it spontaneously generates an in-plane closed flux magnetization pattern (vortex magnetization pattern) while the reference system may be formed such that it provides a non-closed flux magnetization pattern, such as a unidirectional magnetization pattern. A spin valve device with vortex-magnetized free layer will also be referred to as Vortex spin valve device in the following.

One root cause for offset errors in Vortex spin valve bridge sensor configurations is an electrical mismatch between the different branches. This ohmic offset error contribution is usually quite constant over product lifetime and temperature. Consequently, this error can be trimmed by adding a constant voltage to the bridge signal. This trimming procedure works well because the spin valve mismatch value and the trimming devices may be very stable over lifetime and temperature.

An additional offset error source is identified to be related with the Vortex state of spin valve devices. In the ideal case, the Vortex ground state (=magnetization configuration for Hₑₓₜ=0 mT) exhibits Mx=0. Mx=0 results in an electrical spin valve response over a perfectly aligned reference system always the same resistance/conductance value.

As a first order deviation from the ideal case, the Mx magnetization in the Vortex ground state is constant only as long as the Vortex state is not annihilated. After the Vortex state is nucleated again, the ground state Magnetization Mx—which is responsible for the spin valve resistance value—may be different compared to the ground state before the annihilation/nucleation process. This second order effect is not visible for perfect Vortex structures. It requires some asymmetry in the disk geometry, in the lateral variation of the magnetic properties, or in the reference system.

Beside the Vortex asymmetric geometry or inhomogeneous structure, which cannot be avoided in device manufacturing, the Vortex chirality (rotation direction of magnetization pattern) defines the difference in ground state Mx. As long as the Vortex spin valve device nucleates back with the same chirality there is no difference in the ground state magnetization Mx. Unfortunately, the Vortex chirality is not well defined in state-of-the-art solutions. The two different chirality states (clockwise, counterclockwise) result into the same minimum energy, but with different Mx. This may result in bridge offset error after Vortex annihilation/nucleation.

Thus, it is an object of the present disclosure to avoid or at least reduce the described bridge offset error after Vortex annihilation/nucleation.

### SUMMARY

This objective is addressed by devices and methods in accordance with the independent claims. Possibly advantageous implementations are addressed by the dependent claims.

According to a first aspect, the present disclosure provides a spin valve device comprising a layer stack. The layer stack of the spin valve device comprises one or more layers forming a unidirectionally magnetized reference system. The layer stack of the spin valve device further comprises a vortex-magnetized ferromagnetic or ferrimagnetic free layer and a non-magnetic layer separating the reference system from the free layer. The layer stack of the spin valve device further comprises one or more layers forming a bias structure being (bias) exchange-coupled to the free layer. The bias structure has a vortex-magnetization with closed flux of a predetermined rotation direction. The bias structure being exchange-coupled to the free layer allows for a well-defined Vortex chirality and thus Mx magnetization of the spin valve device after the vortex annihilation/nucleation process of the free layer.

In some implementations, the non-magnetic layer comprises a non-conducting material forming a tunnel barrier in a magnetic tunnel junction (MTJ). In this case, the spin valve device may be a MTJ device relying on the TMR effect.

In some implementations, the non-magnetic layer comprises a conducting material forming a GMR junction. In this case, the spin valve device may be a GMR device.

In some implementations, the bias structure is formed as an antiferromagnet (AFM). Alternatively, the bias structure may also be formed as a ferrimagnet or ferromagnet. Both may cause exchange bias or exchange anisotropy occurring in bilayers (or multilayers) of magnetic materials where the hard magnetization behavior of an antiferromagnetic (or ferrimagnetic) layer (bias structure) causes a shift in the soft magnetization curve of a ferromagnetic layer (free layer).

In some implementations, the vortex magnetization of the bias structure is more stable than the vortex magnetization of the free layer. That is, an external magnetic field strength required for annihilating the vortex magnetization of the bias structure may be higher than for annihilating the vortex magnetization of the free layer. The Curie temperature (or blocking temperature) of the bias structure may be lower than that of the free layer. The Curie temperature of the free layer denotes the temperature at which the free layer loses its defined magnetization and changes to a disordered state.

In some implementations, the MTJ device further comprises a non-magnetic or magnetic coupling layer between the free layer and the bias structure. The coupling layer may be used to adjust a coupling strength being a function of the thickness of the coupling layer. For example, the coupling layer may be a Ru (Ruthenium) spacer layer. The coupling can be ferromagnetic or antiferromagnetic.

In some implementations, the reference system is arranged below the free layer (bottom spin valve) whereas the bias structure is arranged above the free layer. Alternatively, the reference system may be arranged above the free layer (top spin valve) whereas the bias structure is arranged below the free layer.

In some implementations, the reference system comprises a first antiferromagnet and the bias structure comprises a second antiferromagnet. The first antiferromagnet may comprise a first material composition or layer thickness different from a second material composition or layer thickness of the second antiferromagnet. This may lead to different blocking temperatures of the first and second antiferromagnets. The blocking temperature denotes the temperature at which a magnetic coupling between the ferromagnet and the adjacent antiferromagnet occurs. Below the blocking temperature, the spins of the ferromagnet align preferred in a direction which is determined by the magnetic moments of the antiferromagnet, while above it, the spins are in random directions.

In some implementations, the first antiferromagnet has a higher blocking temperature than the second antiferromagnet. This means that magnetic thermal annealing of the first antiferromagnet may be performed at a higher annealing temperature than the magnetic thermal annealing of the second antiferromagnet. However, the first antiferromagnet may also have a lower blocking temperature than the second antiferromagnet. This means that magnetic thermal annealing of the first antiferromagnet may be performed at a lower annealing temperature than the magnetic thermal annealing of the second antiferromagnet.

In some implementations, the first antiferromagnet of the reference system may have a lower blocking temperature than the second antiferromagnet of the bias structure. The magnetic thermal annealing of the first and the second antiferromagnet may be performed at an annealing temperature higher than the blocking temperatures of both antiferromagnets (and with a weak magnetic field).

In some implementations, the free layer has a rotationally symmetric or an elliptic shape. For example, the free layer may exhibit a disk shape. Spontaneous vortex formation may be facilitated when a disk shape or a highly symmetric shape is used.

According to a further aspect, the present disclosure provides a method for forming a spin valve device. The method comprises providing one or more layers forming a unidirectionally magnetized reference system, providing a vortex-magnetized free layer, providing a non-magnetic layer (e.g., junction or tunnel barrier) separating the reference system from the free layer, and providing one or more layers forming a bias structure being exchange-coupled to the free layer, wherein the bias structure has a vortex-magnetization with closed flux of a predetermined rotation direction. The spin valve device may be a MTJ device or a GMR device, for example.

In some implementations, the method comprises providing a rotationally symmetric shape to the free layer to spontaneously form a vortex state in the free layer, annealing the bias structure at a first annealing temperature higher than a blocking temperature of the bias structure, and annealing the reference system at a second annealing temperature higher than a blocking temperature of the reference system but lower than the blocking temperature of the bias structure.

In some implementations, an external unidirectional magnetic field is applied during annealing the reference system. No external magnetic field is applied during annealing the bias structure. In this way, a circular shaped exchange bias may form in the bias structure which may then support one defined chirality in the free layer vortex.

In some implementations, an external unidirectional magnetic field is applied during annealing of the reference system and annealing of the bias structure. The reference system and the bias structure may be annealed in one process under the presence of the external unidirectional magnetic field.

In some implementations, an external unidirectional magnetic field is applied during annealing so that at least one layer of the reference system is aligned parallel to a direction of the external unidirectional magnetic field. The external unidirectional magnetic field may be sufficiently small so that the vortex in the free layer is not significantly moved out from the equilibrium direction. Then only one annealing of the entire structure (spin valve) can be performed. Hence the bias structure and the reference system may be annealed in the same process.

### BRIEF DESCRIPTION OF THE DRAWINGS

Some examples of apparatuses and/or methods will be described in the following by way of example only, and with reference to the accompanying figures, in which

FIG. 1A shows a side view of a first layer stack of a spin valve;

FIG. 1B shows a side view of a second layer stack of a spin valve;

FIG. 2A shows a layer stack of a spin valve with a vortex-magnetized free layer;

FIG. 2B illustrates a Wheatstone bridge configuration of spin valves;

FIG. 3 shows vortex-magnetized free layers with different chirality;

FIG. 4A shows a layer stack of a spin valve in accordance with a first implementation;

FIG. 4B shows a layer stack of a spin valve in accordance with a second implementation; and

FIG. 5A-C illustrate a method for forming a spin valve device in accordance with the present disclosure.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

Magneto-resistive sensor devices, for example giant magneto-resistive (GMR) devices or tunnel magneto-resistive (TMR) devices (which are also known as a spin valves) may have a layer stack of alternating ferromagnetic and non-ferromagnetic layers. GMR and TMR spin valves devices will in the following also be commonly referred to as xMR devices.

From the bottom up, an xMR device may, in an example implementation, comprise an antiferromagnetic pinning layer, a ferromagnetic pinned layer, a paramagnetic or diamagnetic coupling layer, a ferromagnetic reference layer with a reference magnetization having a linear or straight pattern, an electrically insulating tunnel barrier or diamagnetic layer, and a ferromagnetic free layer. The skilled person having benefit from the present disclosure will appreciate that the above composition of layers is merely one of many possibilities to form an xMR sensor device. A reverse composition is possible as well. For example, the free layer may be comprised of a composition of ferromagnetic and non-magnetic layers. A free layer composed of a multilayer structure with layers with a conductivity close to the coupling layer and layers with small conductivity further away from the coupling may be beneficial for some applications. The free layer or the pinned layer may be multilayer structures comprising spin injections layers leading to a high spin polarization.

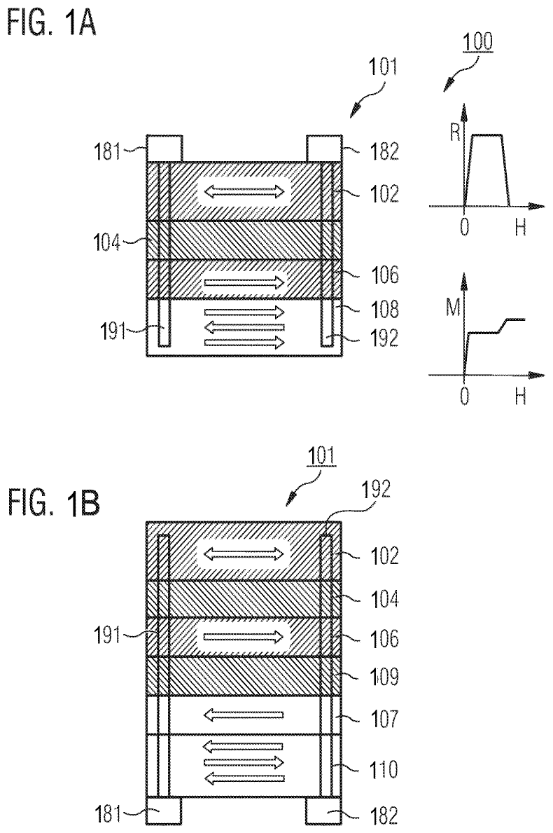

FIGS. 1A and 1B show side views of example implementations of xMR devices 100 with different layer stacks 101.

In the following, GMR devices as examples of xMR devices will be briefly introduced. GMR devices may be operated in a so-called CIP (current-in-plane) configuration, e.g., the applied electrical current flows in parallel to the sheet structure. In the GMR devices, there are some basic types that have gained acceptance in practice. Some example GMR devices for the practical employment are illustrated in FIGS. 1A and 1B.

The GMR device 100 illustrated in FIG. 1A comprises a spin valve system, in which a non-magnetic layer 104 is chosen so thick that no coupling of ferromagnetic layers 102, 106 develops. A lower ferromagnetic layer 106 is strongly coupled to an antiferromagnetic layer 108, so that it gets an unidirectional preferred magnetization direction (so it is not like a permanent magnet because there the two antiparallel states equal in energy) and is magnetically hard (comparable with a permanent magnet). Ferromagnetic layer 106 may be regarded as a reference layer. The upper ferromagnetic layer 102 is soft magnetic and serves as free layer. It may be re-magnetized by already a small external magnetic field M, whereby its electric resistance R changes. The magnetic free layer 102 may be configured to spontaneously generate a closed flux magnetization pattern (not visible in the side views of FIGS. 1A, 1B) in free layer 102. Reference layer 106 has a non-closed flux reference magnetization pattern. Reference layer 106 may be unidirectionally magnetized (e.g., in x-direction). The non-closed flux reference magnetization pattern may in other words correspond to a homogeneous, straight, uniaxial, or linear magnetic field having zero curl and zero divergence. A closed flux magnetization pattern may also be referred to as a vortex state. A spontaneously generated vortex state may for instance form in the free layer 102 directly after its production, or if no external magnetic field is applied.

The vortex-magnetized ferromagnetic free layer 102 is separated, by a non-magnetic layer 104, from the reference layer 106, the unidirectional magnetization direction of which is, however, pinned by the coupling with an antiferromagnetic layer 108 using the so-called “exchange bias interaction”. The principle functioning of a spin valve structure may be illustrated using the magnetization and R(H) curve in FIG. 1A. The magnetization direction of the reference layer 106 may be pinned in negative direction. If the external magnetic field M is increased from negative to positive values, the “free”, ferromagnetic layer 102 may switch near the zero crossing (H=0), and the resistance R may rise sharply. The resistance R may then remain high until the external magnetic field M is large enough to overcome the exchange coupling between the reference layer 106 and the antiferromagnetic layer 108 and to switch also the reference layer 106. In the example of FIG. 1A, the spin valve device 100 is contacted from top using contacts 181 and 182. Optionally, the contacts 181 and 182 may comprise corresponding contact vias 191, 192 vertically extending through one or more (for example all) layers of magneto-resistive layer stack 101. The vias 191, 192 may provide electrical connection to electrical contacts 181, 182 throughout one or more (for example all) layers of magneto-resistive structure 101. Alternatively, the contact pads 181 and 182 could also be located on the bottom.

The GMR layer stack 101 illustrated in FIG. 1B differs from the GMR device illustrated in FIG. 1A in that the lower antiferromagnetic layer 108 of FIG. 1A is replaced by a combination of a natural antiferromagnet (AFM) 110 and a synthetic antiferromagnet 106, 107, 109 (SAF) on top, which is composed of the ferromagnetic layer 106 (reference layer), a ferromagnetic layer 107 (pinned layer), and a non-magnetic coupling layer 109 between. In this manner, the magnetization direction of the magnetic reference layer 106 may be pinned. The upper, ferromagnetic layer 102 again serves as free layer, the Vortex magnetization of which can be manipulated by an external magnetic field M. The advantage of the use of the combination of natural and synthetic antiferromagnets as compared to the construction according to FIG. 1A may be a larger field and temperature stability. In the example of FIG. 1B, the layer stack 101 is contacted from bottom using contacts 181 and 182 including corresponding vias 191, 192 which may provide electrical connection to electrical contacts 181, 182 throughout one or more (for example all) layers of layer stack 101. Alternatively, the contacts 181, 182 could also be located on top.

In the illustrated examples, spin valve layer stacks 101 are implemented as GMR sensor elements in CIP configuration. While in operation, or when coupled to an electric circuit, current flows along the layers (in plane). However, the skilled person having benefit from the present disclosure will appreciate that other implementations may also be implemented as TMR, anisotropic (AMR), colossal (CMR), extraordinary (EMR), or any other xMR sensor element. A TMR device may, for example, be obtained when non-magnetic layer 104 is made of a non-conducting material forming a thin tunnel barrier. TMR devices may be used in a so-called CPP (current-perpendicular-to-plane) configuration.

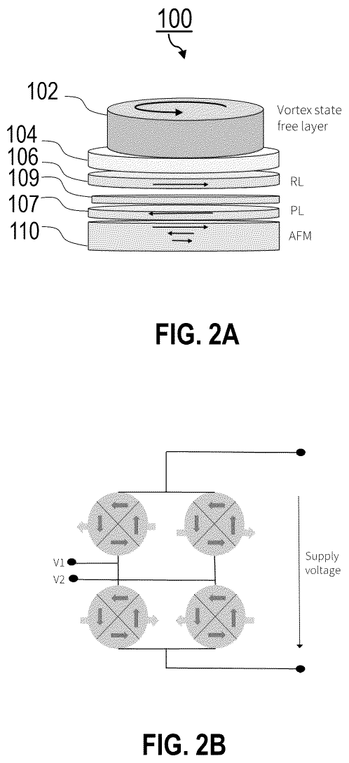

FIG. 2A schematically illustrates a TMR device 200 with a vortex-magnetized ferromagnetic free layer 102.

From the bottom up, TMR device 200 comprises an antiferromagnetic pinning layer 110 and a ferromagnetic pinned layer 107. Contact between pinning layer 110 and pinned layer 107 provokes the exchange bias effect, causing the magnetization of pinned layer 107 to align in a preferred (unidirectional) direction. In other words, pinned layer 107 may exhibit a linear magnetic flux pattern which, in the example of FIG. 2A, is parallel to the x-direction. TMR device 200 further comprises a coupling layer 109. Coupling layer 109 may be diamagnetic and for example comprise ruthenium (Ru), iridium (Ir), copper (Cu) or copper alloys and similar materials. Coupling layer 109 spatially separates pinned layer 107 from ferromagnetic reference layer 106. Using this setup, magnetization of reference layer 106 may align and be held in a direction anti-parallel to the magnetization of pinned layer 107. TMR device 200 also comprises a tunnel barrier 104 which is electrically insulating and separates reference layer 106 from a ferromagnetic free layer 102. For example, the tunnel barrier might contain MgO, AlO or TiO. Free layer 102, reference layer 106 and pinned layer 107 may in some implementations comprise iron (Fe), cobalt (Co) or nickel (Ni), and in some further implementations, alloys of these. Alloys may also comprise non-ferromagnetic materials, e.g., carbon, boron, nitrogen and oxygen, with ferromagnetic materials constituting at least 50% of a material composition of the respective layer. For example, layers may comprise cobalt-iron (CoFe), CoFeB, or nickel-iron, NiFe, alloys. In contrast, pinning layer 111 may comprise for example iridium, manganese, platinum, or alloys comprising these.

While in operation, or when coupled to an electric circuit, electrical charges may pass from one side of tunnel barrier 104 to the other (CPP) in a predetermined amount if an external magnetic field is applied. The TMR effect is a quantum physical phenomenon expressing itself in a change of the amount of charges passing the tunnel barrier 104 when the direction of the external magnetic field is changed. This effect may arise due to directional changes of the magnetization of free layer 102 caused by the changing external magnetic field.

Free layer 116 in FIG. 2A is of circular shape, or, in other words, has a disk-like structure. The disk has a diameter d which may, for example be in a range of one hundred nm to 10 μm. The disk further has a thickness tin the range of e.g., 10 nm to 300 nm. The thickness may exceed a thickness of the reference layer 106. Providing a layer having a rotationally symmetric structure may lead to spontaneous formation of a closed flux magnetization pattern in free layer 102. Depending on the exact shape of free layer 102, the closed flux magnetization pattern may, for instance, comprise at least partially a Landau pattern, a circumferential pattern, a vortex pattern, or a combination of any of the previously mentioned patterns. A Landau pattern comprises at least partially a polygon-like closed shape, while a circumferential pattern may comprise a smoother, rounder closed shape. A pure vortex pattern may be essentially circular. However, an in-plane closed flux magnetization pattern may comprise any combination of the previously mentioned patterns. Moreover, a closed magnetization line of a magnetization pattern may be fully shaped according to any of the previously mentioned patterns but may also comprise sections following a different closed flux magnetization pattern. The different types of closed flux magnetization pattern may also be commonly referred to as vortex. The vortex state may in other words be obtained by choosing the disk thickness tin the range of e.g., 30 nm to 300 nm and the disk diameter d between 500 nm and 5 μm (see, e.g., Scholz, W., Guslienko, K. Novosad, V., Suess, D., Schrefl. T., Chantrell. R. W., & Fidler, J. 2003). Transition from single-domain to vortex state in soft magnetic cylindrical nanodots. Journal of magnetism and magnetic materials, 266(1-2), 155-163). In a vanishing external magnetic field, a center of the vortex may be essentially located at a center of the magnetic free layer 102 such that a net magnetization of the respective magnetic free layer essentially vanishes.

A magnetic xMR sensor concept with a free layer 102 in vortex configuration may have nearly zero hysteresis which may be especially interesting in applications such as wheel speed sensing or current sensing. Prerequisite for low hysteresis may be the presence of the vortex state. Critical parameters which may describe the regime in which the vortex state exists are nucleation field Hn, where the vortex nucleates, and annihilation field Han, where it gets destroyed again.

xMR devices with free layers 102 in vortex configuration may be used in the form of Wheatstone bridge configurations to sense magnetic fields. A Wheatstone bridge configuration is generally known in the art and illustrated in FIG. 2B. In the ideal use case, the xMR devices used in the bridge configuration are matched in terms of electrical resistance and magnetic sensitivity over different operating conditions (e.g.: temperature, supply voltage). One root cause for offset errors in Vortex xMR bridge configuration is an electrical mismatch between different branches (e.g., left and right branch). This ohmic offset error contribution is usually quite constant over product lifetime and temperature. As a consequence, this error can be trimmed by adding a constant voltage to the bridge signal (V1-V2). This trimming procedure works very well because the xMR mismatch value and the trimming devices are very stable over lifetime and temperature. An additional offset error source is identified to be related with the Vortex state of the xMR devices. In the ideal case (see FIG. 2) the Vortex ground state (=magnetization configuration for Hₑₓₜ=0 mT) exhibits Mx=0. Mx=0 results in the electrical xMR response over a perfectly aligned reference system always the same resistance/conductance value. In such a Wheatstone bridge configuration, the reference system orientation might be in opposing directions in two of the sensors in order to realize a linear field sensor. These different reference layer directions of the magnetization might be realized by locally heating individual elements by laser annealing and applying fields in different directions, when different elements are laser annealed.

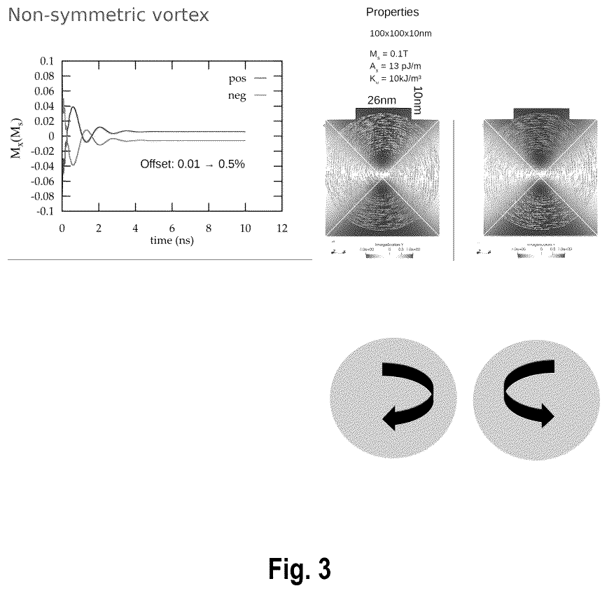

As a first order deviation from an ideal case, a Mx magnetization in a Vortex ground state is constant only as long as the Vortex state is not annihilated. After the Vortex state is nucleated again, the ground state Magnetization Mx—which is responsible for the xMR device's resistance value—may be different compared to the ground state before annihilation/nucleation process. This second order effect is not visible for perfect Vortex structures. It requires some asymmetry in the disk geometry or also reference system (see FIG. 3).

Beside the Vortex asymmetric geometry or inhomogeneous structure, which cannot be avoided in device manufacturing, the Vortex chirality (Vortex rotation direction) defines the difference in ground state Mx. As long as the Vortex xMR device nucleates back with the same chirality there is no difference in the ground state magnetization Mx detected.

To have a well-defined Mx magnetization after annihilation/nucleation process, the Vortex chirality should be well defined. Well defined means that the Vortex chirality of free layer 102 should not be changed by subsequent annihilation/nucleation processes. One additional, but important, boundary condition may be that the Vortex chirality should be defined for each annihilation/nucleation process. Vortex annihilation can be achieved with any field direction, the applied field strength must be larger than annihilation field Han but the direction can be arbitrary. The same condition holds for Vortex nucleation. A problem is to define the Vortex chirality for all possible conditions.

The present disclosure proposes to solve this problem by applying a bias field effect directly on the free layer 102 of a xMR or spin valve device. The applied bias field should have a Vortex magnetization with a defined chirality. The effect to generate the bias field may be the exchange bias (EB) effect—a bias effect between a ferromagnetic material (FM) layer (free layer 102) and a bias structure, which is deposited on top of the free layer 102.

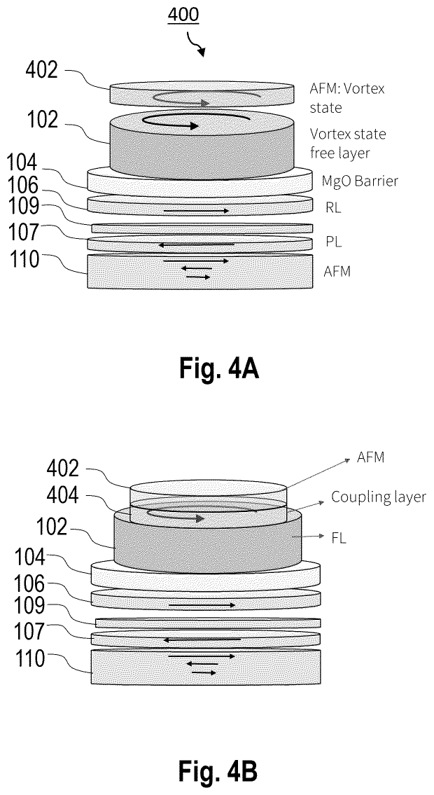

A first implementation of a spin valve device 400 according to an implementation of the present disclosure is shown in FIG. 4A.

Like the spin valve devices 100, 200 mentioned above, spin valve device 400 comprises a layer stack which comprises one or more layers 106, 107, 109, 110 forming a unidirectionally magnetized reference system, a vortex-magnetized ferromagnetic free layer 102, a non-magnetic layer 104 separating the reference system 106, 107, 109, 110 from the free layer 102. The skilled person having benefit from the present disclosure will appreciate that the reference system may alternatively comprise layers 106 and 108, like in FIG. 1A. Non-magnetic layer 104 may be configured as a tunnel barrier or a GMR junction, depending on whether device 400 is a MTJ (magnetic tunnel junction) or a GMR device.

Additionally, spin valve device 400 comprises one or more layers forming a bias structure 402 being exchange-coupled to the free layer 102. The bias structure 402 has a vortex-magnetization with closed flux of a predetermined rotation direction (predetermined Vortex chirality). As indicated in FIG. 4A, bias structure 402 may be formed as a (natural) antiferromagnet being exchange-coupled to the free layer 102. Alternatively, bias structure 402 may also be formed as a ferrimagnet or a ferromagnet with high coercivity being exchange-coupled to the free layer 102. The vortex magnetization of the bias structure 402 may be more stable than the vortex magnetization of the free layer 102 meaning that an external magnetic field strength required for annihilating the vortex magnetization of the bias structure 402 may be higher than for annihilating the vortex magnetization of the free layer 102.

Thus, one technical implementation is to deposit an additional antiferromagnetic layer 402 on top of the free layer 102. An example of a material composition of the free layer 102 is NiFe, e.g., Ni₈₀Fe₂₀. Another example of the material composition of the free layer 102 is CoFe, e.g., Co₉₀Fe₁₀ or Ca₇₀Fe₃₀. Yet another example of the material composition of the free layer 102 is CoFeB, e.g., Co₆₀Fe₂₀B₂₀ or Co₇₂Fe₈B₂₀. Examples of material compositions of the antiferromagnet 402 are PtMn, IrMn, NiMn, MnN. The skilled person having benefit from the present disclosure will appreciate that the antiferromagnet 402 may also be deposited below the free layer 102, e.g., in a top spin valve (TSV) arrangement. Additional because antiferromagnetic pinning layer 402 may be identical to antiferromagnetic pinning layer 110 used in the magnetic reference system 106, 107, 109, 110. To get a defined exchange bias in the reference system 106, 107, 109, 110 and in the free layer system the two antiferromagnetic layer material systems may be correlated.

Usually, the antiferromagnetic pinning layer 110 in the reference system has a higher blocking temperature. This means a temperature required for annihilating the unidirectional reference magnetization (example in x-direction). After device structuring the Vortex state may be spontaneously formed in the free layer 102. In a second anneal step, in which the temperature is higher than the blocking temperature of the exchange-coupled free layer material but lower than the blocking temperature of the reference system, the Vortex magnetization of the free layer 102 gets imprinted in the bias structure 402. After this step we have a Vortex pattern with a defined chirality in the additional bias structure 402. This exchange bias effect may define the Vortex xMR chirality for the free layer 102 after arbitrary vortex annihilation/nucleation processes.

A further possible implementation is illustrated in FIG. 4B and can be realized by using a non-magnetic or magnetic coupling layer 404 between the free layer 102 and the (exchange) bias structure 402. Using the coupling layer 404 the exchange bias between the free layer 102 and the (exchange) bias structure 402 and/or a hysteresis may be tuned.

In an example implementation without coupling layer, a free layer 102 of e.g., 80 nm CoFeB and a bias structure 402 with an antiferromagnetic layer 402 of 5 nm IrMn may be used. In an example implementation with coupling layer 104, a free layer 102 of e.g., 80 nm CoFeB, a coupling layer of 3 nm CoFe, and a bias structure 402 with an antiferromagnetic layer 402 of 5 nm IrMn may be used. In an example with ferromagnetic and non-ferromagnetic coupling layer, a free layer 102 of e.g., 80 nm CoFeB, non-ferromagnetic coupling layer of 0.2 nm Ta, a ferromagnetic coupling layer of 3 nm CoFe, and a bias structure 402 with an antiferromagnetic layer 402 of 5 nm IrMn may be used.

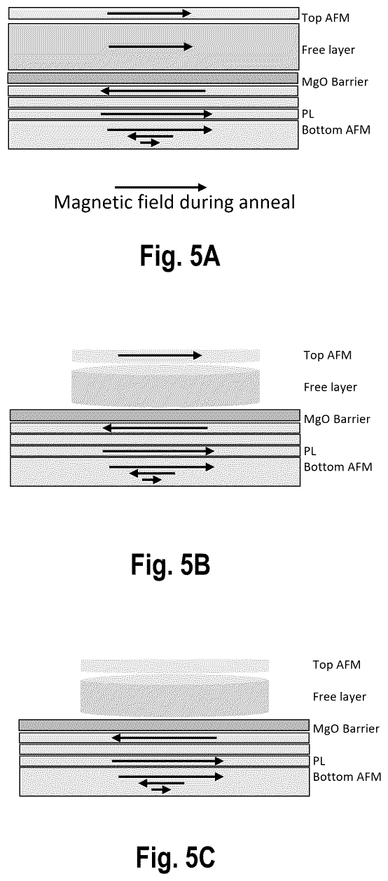

Referring now to FIGS. 5A-C, an implementation of a process for forming a spin valve device in accordance with the present disclosure will be described.

FIG. 5A illustrates an act of forming a spin valve layer stack including one or more layers forming a unidirectionally magnetized reference system 106, 107, 109, 110, a vortex-magnetized ferromagnetic free layer 102, and a non-magnetic layer 104 separating the reference system from the free layer 102. Forming the spin valve layer stack further includes forming one or more layers forming a bias structure (antiferromagnetic layer) 402. The bias structure 402 may be provided above (on top of) the free layer 102. As further shown in FIG. 5A, the reference system 106, 107, 109, 110 may be annealed at a first magnetic annealing temperature higher than a blocking temperature of the reference system 106, 107, 109, 110.

In a further act shown in FIG. 5B, respective a rotationally symmetric or elliptic shapes may be formed in the free layer 102 and the layer(s) of bias structure 402 to spontaneously form a vortex state in the free layer 102 and/or the bias structure 402. Here, a circular magnetization may build up in the free layer 102, since the exchange bias of bias structure 402 is too weak for linear alignment of magnetization.

In a further act shown in FIG. 5C, the antiferromagnetic layer(s) of bias structure 402 may be magnetically annealed at a second magnetic annealing temperature higher than a blocking temperature of the bias structure 402. The second magnetic annealing temperature may be higher than the blocking temperature of the reference system 106, 107, 109, 110. This may be achieved, for example, when the antiferromagnet of the reference system 106, 107, 109, 110 comprises a different material composition or layer thickness than the antiferromagnet of the bias structure 402. For example, PtMn has a higher blocking temperature compared to IrMn. 5 nm IrMn has a lower blocking temperature than 10 nm IrMn. At the second magnetic annealing temperature, the vortex-magnetization of the free layer 102 may be imprinted (pinned) into the bias structure 402. After cool-down without any external magnetic field, a circular shaped exchange bias forms in the top antiferromagnet 402 and supports one defined chirality in the free layer vortex. The bottom exchange bias of reference system 106, 107, 109, 110 stays in its original direction.

While a BSV (bottom spin valve shown) in FIGS. 5A-C, the same principle also works for a TSV (top spin valve).

The present disclosure proposes spin valves with unidirectional magnetized reference system in combination with circumferential magnetized free layer (Vortex magnetization). The free layer exhibits a Vortex magnetization without any bias field contributions. The free layer Vortex is formed spontaneously after structuring to a proper D/t dimension (D=diameter, t=thickness). On top of the Vortex type free layer an antiferromagnetic layer may be placed in order to bias the free layer chirality after annihilation/nucleation processes. The exchange bias on the free layer defines not the Vortex magnetization only the Vortex chirality.

The antiferromagnet may be configured by different material compositions, different crystallinity, or layer thickness to differ from the antiferromagnet in the reference system. Different blocking temperature distributions are needed to define Vortex magnetization in the antiferromagnetic layer without degrading the reference layer orientation.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A spin valve device, comprising:
a layer stack comprising:
one or more layers forming a unidirectionally magnetized reference system;
a vortex-magnetized free layer;
a non-magnetic layer separating the unidirectionally magnetized reference system from the vortex-magnetized free layer; and
one or more layers forming a bias structure being exchange-coupled to the vortex-magnetized free layer, the bias structure having a vortex-magnetization with closed flux of a predetermined rotation direction.

2. The spin valve device of claim 1, wherein the non-magnetic layer comprises a non-conducting material forming a tunnel barrier.

3. The spin valve device of claim 1, wherein the non-magnetic layer comprises a conducting material forming a giant magneto resistance junction.

4. The spin valve device of claim 1, wherein the bias structure is formed as an antiferromagnet.

5. The spin valve device of claim 1, wherein the bias structure is formed as a ferrimagnet.

6. The spin valve device of claim 1, wherein an external magnetic field strength required for annihilating the vortex magnetization of the bias structure is higher than for annihilating a vortex magnetization of the vortex-magnetized free layer.

7. The spin valve device of claim 1, further comprising a non-magnetic coupling layer or a magnetic coupling layer between the vortex-magnetized free layer and the bias structure.

8. The spin valve device claim 1, wherein the unidirectionally magnetized reference system and the bias structure are arranged on different sides of the vortex-magnetized free layer.

9. The spin valve device claim 1, wherein the unidirectionally magnetized reference system comprises a first antiferromagnet and the bias structure comprises a second antiferromagnet, wherein the first antiferromagnet comprises a first material composition that is different from a second material composition of the second antiferromagnet or a first layer thickness that is different from a second layer thickness of the second antiferromagnet.

10. The spin valve device claim 1, wherein the unidirectionally magnetized reference system comprises a first antiferromagnet and the bias structure comprises a second antiferromagnet, wherein the first antiferromagnet has a different blocking temperature that is different than a blocking temperature of the second antiferromagnet.

11. The spin valve device of claim 1, wherein the vortex-magnetized free layer has a rotationally symmetric shape.

12. A method for forming a spin valve device, the method comprising:
providing one or more layers forming a unidirectionally magnetized reference system;
providing a vortex-magnetized free layer;
providing a non-magnetic layer separating the unidirectionally magnetized reference system from the vortex-magnetized free layer; and
providing one or more layers forming a bias structure being exchange-coupled to the vortex-magnetized free layer, the bias structure having a vortex-magnetization with closed flux of a predetermined rotation direction.

13. The method of claim 12, wherein the method further comprises:
providing a rotationally symmetric shape to the vortex-magnetized free layer to spontaneously form a vortex state in the vortex-magnetized free layer;
annealing the bias structure at a first annealing temperature that is higher than a blocking temperature of the bias structure; and
annealing the unidirectionally magnetized reference system at a second annealing temperature that is higher than a blocking temperature of the unidirectionally magnetized reference system and is lower than the blocking temperature of the bias structure.

14. The method of claim 13, wherein an external unidirectional magnetic field is applied during annealing the unidirectionally magnetized reference system and wherein no external magnetic field is applied during annealing the bias structure.
